(19) United States
(12) Patent Application Publication
(10) Pub. No.: US 2011/0273020 A1
(43) Pub. Date: Nov. 10, 2011

(54) Integrated Photovoltaic Module

(75) Inventors: Dhanushan Balachandreswaran, Richmond Hill (CA); Jana Shaw, Bolton (CA)

(73) Assignee: MORGAN SOLAR INC., Toronto (CA)

(21) Appl. No.: 13/078,724

(22) Filed: Apr. 1, 2011

Related U.S. Application Data
(60) Provisional application No. 61/320,149, filed on Apr. 1, 2010.

(51) Int. Cl. H01L 31/052; H02J 1/10

(52) U.S. Cl. 307/71; 136/246

(57) ABSTRACT

A light concentrating photovoltaic system and method is provided to address potential degradation in performance of optical concentrator and PV cell assemblies, whether due to misalignments of various components within the optical concentrator (such as light guides, focusing elements and the like), misalignment between the optical concentrator and the PV cell, or other anomalies or defects within any such component. Within a single apparatus, a number of optical concentrators and corresponding sunlight receiver assemblies (including the PV cell) are provided each with a corresponding integrated power efficiency optimizer to adjust the output voltage and current of the PV cell resulting from differing efficiencies between each one of the concentrator-receiver assemblies.

### REFERENCE TO PRIOR APPLICATIONS

This application claims priority to U.S. Application No. 61/320,149, filed Apr. 1, 2010, entitled “Photovoltaic Solar Concentrator with Multiple Output Power Conditioning Components and Functions Embedded at the Individual Optical Photovoltaic Cell Level”.

### TECHNICAL FIELD

The present application relates to the field of solar energy. In particular, the present application relates to the optimization of concentrated photovoltaic solar energy systems.

### DESCRIPTION OF THE RELATED ART

Despite the natural abundance of solar energy, the ability to efficiently harness solar power as a cost-effective source of electrical power remains a challenge.

Solar power is typically captured for the purpose of electrical power production by an interconnected assembly of photovoltaic (PV) cells arranged over a large surface area of one or more solar panels. Multiple solar panels may be arranged in arrays.

A longstanding problem in the development of efficient solar panels has been that the power generated by each string of PV cells is limited by the lowest performing PV cell when the PV cells act as current sources. Similarly, an array of solar panels is limited by its lowest performing solar panel when the solar panels are connected in series. Thus, a typical solar panel can underperform when the output power of the solar panel differs from other solar panels of the array it supports. The ability to convert the solar energy impinging upon a PV cell, panel or array is therefore limited, and the physical integrity of the solar panels may be compromised by exposure to heat dissipated due to unconverted solar energy.

PV cells of a string may perform differently from one another due to inconsistencies in manufacturing, and operating and environmental conditions. For example, manufacturing inconsistencies may cause two otherwise identical PV cells to have different output characteristics. The power generated by PV cells is also affected by external factors such as shade and operating temperature. Therefore, in order to make the most efficient use of PV cells, manufacturers bin or classify each PV cell based on their efficiency, their expected temperature behaviour and other properties, and create solar panels with similar, if not identical, PV cell efficiencies. Failure to classify cells in this manner before constructing a panel can lead to cell-level mismatches and underperforming panels. However, this assembly line classification process is time consuming, costly, and occupies a large footprint on the plant floor (as solar simulators and automatic sorting and binning machines, such as electroluminescent imaging systems, are required to characterize the PV cells), but has been crucial to improving the efficiency of solar panels.

To improve the efficiency of capturing solar radiation, optical concentrators may be used to collect light incident upon a large surface area and direct or concentrate that light onto a small PV cell. A smaller active PV cell surface may therefore be used to achieve the same output power. Concentrators generally comprise one or more optical elements for the collection and concentration of light, such as lenses, mirrors or other optically concentrative devices retained in a fixed spatial position relative to the PV cell and optically coupled to the aperture of the PV cell.

However, concentrated photovoltaic systems introduce a further level of complexity to the problem of mismatched PV cell efficiencies because inconsistencies in manufacturing, and operating and environmental conditions of optical concentrators may also degrade the performance of optical modules (the optical modules comprising the concentrator in optical communication with the PV cell). For example, point defects in the concentrator, angular or lateral misalignment between the optical concentrator and PV cell causing misdirection of the sun's image on the active surface of the PV cell, solar tracking errors, fogging, dust or snow accumulation, material change due to age and exposure to nature's elements, bending, defocus and staining affect the performance of optical modules. Furthermore, there may be losses inherent in the structure of the optical modules. For example, there may be transmission losses through the protective cover of the optical concentrator, mirror reflectivity losses, or secondary optical element losses including absorption and Fresnel reflection losses. If the efficiency of optical concentrators within a solar panel are not matched, the performance of the panel or array will be downgraded to the level of the lowest performing optical module due to mismatching PV cell properties such as fluctuating cell output voltages and/or current.

Thus, the conventional manufacture of concentrated photovoltaic systems requires sorting and binning of PV cells for their efficiencies and other PV properties, sorting and binning of optical concentrators and sorting and binning of optical modules.

There is therefore a need for a concentrated photovoltaic system and method that reduces the need for the sorting and binning process to reduce manufacturing time and cost. There is also a need to overcome or reduce the degradation in performance due to irregularities in optical concentrator and PV cell power output in order to improve the efficiency of concentrated photovoltaic solar panels. Furthermore, modularity of concentrated photovoltaic components may facilitate maintenance and repair of concentrated photovoltaic systems.

### SUMMARY

A light concentrating photovoltaic system and method is provided to address potential degradation in performance of optical concentrator and PV cell assemblies, whether due to misalignments of various components within the optical concentrator (such as light guides, focusing elements and the like), misalignment between the optical concentrator and the PV cell, or other anomalies or defects within any such component. Within a single apparatus, a number of optical concentrators and corresponding sunlight receiver assemblies (including the PV cell) are provided each with a corresponding integrated power efficiency optimizer to adjust the output voltage and current of the PV cell resulting from differing efficiencies between each one of the concentrator-receiver assemblies.

Additional and alternative features, aspects, and advantages of the embodiments described herein will become apparent from the following description, the accompanying drawings, and the appended claims.

### BRIEF DESCRIPTION OF THE DRAWINGS

In drawings which illustrate by way of example only a preferred embodiment of the invention,

FIG. 1 is a schematic diagram of an embodiment of a sunlight concentration photovoltaic (CPV) module;

FIG. 2A is an elevation view of an optical concentrator;

FIG. 2B is an enlarged view of the central portion of FIG. 2A, illustrating the propagation of sunlight therein to a PV cell;

FIG. 3 is an exploded perspective view of another embodiment of a optical concentrator;

FIGS. 4A to 4I illustrate alternative embodiments of optical concentrators;

FIG. 5A is an elevation view of another embodiment of an optical concentrator;

FIG. 5B is an enlarged view of a portion of the optical concentrator of FIG. 5A;

FIG. 6A is an illustration of a sun image on a perfectly aligned PV cell;

FIG. 6B is an illustration of a sun image on a misaligned PV cell;

FIG. 7A is an illustration of a typical I-V curve of a PV cell at various operating temperatures;

FIG. 7B is an illustration of a typical P-V curve of a PV cell at various operating temperatures;

FIG. 8A is a plan view of a first side of an embodiment of a receiver assembly;

FIG. 8B is a plan view of a second side of an embodiment of a receiver assembly comprising a multi-chip integrated power efficiency optimizer;

FIG. 8C is a side view of the embodiment of the receiver assembly of FIGS. 7A and 7B;

FIG. 9 is a plan view of another embodiment of a receiver assembly comprising a integrated power efficiency optimizer system-on-a-chip;

FIG. 10 is a plan view of an embodiment of a receiver assembly comprising two separate printed circuit boards;

FIG. 11A is a plan view of a first side of an embodiment of a receiver assembly powered by a secondary PV cell;

FIG. 11B is a plan view of a second side of an embodiment of a receiver assembly comprising a multi-chip integrated power efficiency optimizer powered by a secondary PV cell;

FIG. 12 is a plan view of a first side of another embodiment of a receiver assembly;

FIG. 13 is a block diagram of the integrated power efficiency optimizer system;

FIG. 14 is a block circuitry diagram of an embodiment of a receiver assembly powered by a optical module;

FIG. 15 is a block circuitry diagram of an embodiment of a receiver assembly powered by a optical module and/or an auxiliary power source without a battery;

FIG. 16 is a block circuitry diagram of an embodiment of a receiver assembly powered by a optical module and/or an auxiliary power source with a battery;

FIG. 17 is a block circuitry diagram of an embodiment of a receiver assembly with communication circuitry;

FIG. 18 is a block circuitry diagram of an embodiment of a receiver assembly with a DC/AC inverter;

FIG. 19A is a block diagram of integrated CPV modules with AC output connected in series;

FIG. 19B is a block diagram of integrated CPV modules with AC output connected in parallel;

FIG. 20A is a block diagram of integrated CPV modules with DC output connected in series;

FIG. 20B is a block diagram of integrated CPV modules with DC output connected in parallel;

FIG. 21 is a block diagram of integrated CPV modules with DC output connected in parallel and a second stage DC/AC inverter;

FIG. 22 is a block diagram of an array of integrated CPV modules with DC output and a second stage DC/AC inverter;

FIG. 23A is plan view of an embodiment of a CPV panel;

FIG. 23B is a plan view of an embodiment of a string of CPV cells;

FIG. 23C is an exploded side view of an embodiment of an integrated CPV module; and,

FIG. 24 is a perspective view of a solar panel.

### DETAILED DESCRIPTION

The embodiments described herein provide a sunlight concentration photovoltaic (CPV) apparatus and method of converting solar power to electrical power by an array of interconnected photovoltaic (PV) cells. These embodiments provide localized power conditioning of output from a PV cell receiving concentrated light, and thereby ameliorate at least some of the inconveniences present in the prior art.

In one embodiment there is provided a sunlight concentration photovoltaic apparatus comprising a plurality of optical concentrators adapted to receive input sunlight, each optical concentrator comprising at least one optical element having a first optical efficiency and each one of the plurality of optical concentrators having a corresponding second optical efficiency, a plurality of sunlight receiver assemblies, each sunlight receiver assembly comprising a photovoltaic cell arranged to receive sunlight output from a corresponding one of the plurality of optical concentrators and an integrated power efficiency optimizer in electrical communication with said photovoltaic cell, the integrated power efficiency optimizer being configured to adjust an output voltage and current of said photovoltaic cell to reduce loss of output power of the plurality of the photovoltaic cells resulting from differences amongst the second optical efficiencies of the plurality of optical concentrators, the second optical efficiency of each one of the plurality of optical concentrators being dependent on at least a relative positioning of the at least one optical elements and the corresponding photovoltaic cell for said optical concentrator.

In further aspects of this embodiment the first optical efficiency comprises a measurable difference between an amount of sunlight input at said at least one optical element and an amount of sunlight output from said at least one optical element; the at least one optical element comprises a lens, a waveguide or a curved reflective surface; the first optical efficiency is reduced by an anomaly comprised in the at least one optical element, the anomaly selected from the group consisting of an optical aberration, material absorption, degradation of at least one sunlight impinging surface, a change in the shape of at least one sunlight impinging surface, escape of light before reaching an output surface of the optical element and any combination thereof; each second optical efficiency is dependent on the first optical efficiencies of said at least one optical element; each second optical efficiency varies over time; each of the integrated power efficiency optimizers continuously adjusts the output voltage and current of the photovoltaic cell with which the integrated power efficiency optimizer is in electrical communication as the second optical efficiency varies over time; each of said sunlight receiver assemblies comprises a substrate bearing said photovoltaic cell and said integrated power efficiency optimizer, and wherein said integrated power efficiency optimizer is disposed proximate to the photovoltaic cell; each of said integrated power efficiency optimizers further comprises a rectifier and a DC/DC converter; each of said integrated power efficiency optimizers further comprises a DC/AC inverter; at least one of the sunlight receiver assemblies further comprises communications circuitry; at least one of the sunlight receiver assemblies further comprises at least one bypass diode and bypass control circuitry; the integrated power efficiency optimizers of said plurality of sunlight receiver assemblies are interconnected in series at a first stage with DC output, the DC output being converted to AC by a DC/AC inverter at a second stage; the integrated power efficiency optimizers of said plurality of sunlight receiver assemblies are interconnected in parallel at a first stage with DC output, the DC output being converted to AC by a DC/AC inverter at a second stage; and/or the integrated power efficiency optimizers of said plurality of sunlight receiver assemblies are interconnected in a combination of series and parallel connections at a first stage with DC output, the DC output being converted to AC by a DC/AC inverter at a second stage.

In another embodiment there is provided a method for conversion of solar power to electrical power by an array of interconnected photovoltaic cells, the method comprising, for each photovoltaic cell in said array, receiving sunlight through a corresponding optical concentrator adapted to receive input sunlight, the optical concentrator comprising at least one optical element having a first optical efficiency and each one of the plurality of optical concentrators having a corresponding second optical efficiency, said second optical efficiency being dependent on at least a relative positioning of the at least one optical element and the corresponding photovoltaic cell for said optical concentrator; simultaneously adjusting an output voltage and current of each of the photovoltaic cells in the array to reduce loss of output power of the array resulting from differences amongst the second optical efficiencies of the array and converting an output power of each of the photovoltaic cells in the array using integrated power efficiency optimizers, each one of said integrated power efficiency optimizers being in electrical communication with a corresponding one of the photovoltaic cells; and combining the converted output power from each of the integrated power efficiency optimizers.

In further aspects of this embodiment the first optical efficiency comprises a measurable difference between an amount of sunlight input at said at least one optical element and an amount of sunlight output from said at least one optical element and wherein the first optical efficiency is reduced by an anomaly comprised in the at least one optical element, the anomaly selected from the group consisting of an optical aberration, material absorption, degradation of at least one sunlight impinging surface, a change in the shape of at least one sunlight impinging surface, escape of light before reaching an output surface of the optical element and any combination thereof; the second optical efficiency is dependent on the first optical efficiencies of the at least one optical element and wherein the output voltage and current of each photovoltaic cell are continuously adjusted over time as the second optical efficiency of the optical concentrator from which concentrated sunlight is received varies over time; and/or adjusting the output voltage and current of each of the photovoltaic cells in the array comprises sensing an output current and an output voltage of each said photovoltaic cell, and locking one of the output current or output voltage to the maximum power point.

In a further embodiment there is provided a sunlight concentration photovoltaic apparatus comprising a plurality of optical concentrators adapted to receive input sunlight, each optical concentrator comprising at least one focusing element having a first optical efficiency and at least one light guide having a second optical efficiency, the at least one light guide being optically coupled to the at least one focusing element, each one of the plurality of optical concentrators having a corresponding third optical efficiency, a plurality of sunlight receiver assemblies, each sunlight receiver assembly comprising a photovoltaic cell arranged to receive sunlight output from a corresponding one of the plurality of optical concentrators and an integrated power efficiency optimizer in electrical communication with said photovoltaic cell, the integrated power efficiency optimizer being configured to adjust an output voltage and current of said photovoltaic cell to reduce loss of output power of the plurality of the photovoltaic cells resulting from differences amongst the third optical efficiencies of the plurality of optical concentrators, the third optical efficiency of each one of the plurality of optical concentrators being dependent on at least a relative positioning of the at least one focusing element, the at least one light guide of said optical concentrator and the corresponding photovoltaic cell for said optical concentrator.

In further aspects of this further embodiment the first optical efficiency comprises a measurable difference between an amount of sunlight input at said at least one focusing element and an amount of sunlight output from said at least one focusing element; the at least one focusing element comprises a lens or a curved reflective surface; the first optical efficiency is reduced by an anomaly comprised in the at least one focusing element, the anomaly selected from the group consisting of an optical aberration, material absorption, degradation of at least one sunlight impinging surface, a change in the shape of at least one sunlight impinging surface and any combination thereof; the second optical efficiency comprises a measurable difference between an amount of sunlight input at said least one light guide and an amount of sunlight output from said at least one light guide toward the photovoltaic cell; the second optical efficiency is reduced by an anomaly comprised in the at least one light guide, the anomaly selected from the group consisting of an optical aberration, material absorption, degradation of at least one light impinging surface, a change in the shape of at least one light impinging surface, premature escape of light from the at least one light guide and any combination thereof; each third optical efficiency is dependent on the first optical efficiencies of the at least one focusing element; each third optical efficiency is dependent on the first optical efficiency and the second optical efficiency; each third optical efficiency varies over time; each of the integrated power efficiency optimizers continuously adjusts the output voltage and current of the photovoltaic cell with which the integrated power efficiency optimizer is in electrical communication as the third optical efficiency varies over time; each of said sunlight receiver assemblies comprises a substrate bearing said photovoltaic cell and said integrated power efficiency optimizer, and wherein said integrated power efficiency optimizer is disposed proximate to the photovoltaic cell; each of said integrated power efficiency optimizers is powered by at least one corresponding secondary photovoltaic cell; the integrated power efficiency optimizers of said plurality of sunlight receiver assemblies are interconnected in series at a first stage with DC output, the DC output being converted to AC by a DC/AC inverter at a second stage; the integrated power efficiency optimizers of said plurality of sunlight receiver assemblies are interconnected in parallel at a first stage with DC output, the DC output being converted to AC by a DC/AC inverter at a second stage; the integrated power efficiency optimizers of said plurality of sunlight receiver assemblies are interconnected in a combination of series and parallel connections at a first stage with DC output, the DC output being converted to AC by a DC/AC inverter at a second stage; and/or the integrated power efficiency optimizer of at least one of the sunlight receiver assemblies comprises a system-on-a-chip.

In yet another embodiment there is provided a method for conversion of solar power to electrical power by an array of interconnected photovoltaic cells, the method comprising, for each photovoltaic cell in said array, receiving sunlight through a corresponding optical concentrator adapted to receive input sunlight, the optical concentrator comprising at least one focusing element having a first optical efficiency and at least one light guide having a second optical efficiency, the at least one light guide being optically coupled to the at least one focusing element, each one of the plurality of optical concentrators having a corresponding third optical efficiency, said third optical efficiency being dependent on at least a relative positioning of the at least one focusing element, the at least one light guide of said optical concentrator and the corresponding photovoltaic cell for said optical concentrator, simultaneously adjusting an output voltage and current of each of the photovoltaic cells in the array to reduce loss of output power of the array resulting from differences amongst the third optical efficiencies of the array and converting an output power of each of the photovoltaic cells in the array using integrated power efficiency optimizers, each one of said integrated power efficiency optimizers being in electrical communication with a corresponding one of the photovoltaic cells, and combining the converted output power from each of the integrated power efficiency optimizers.

In further aspects of this embodiment the first optical efficiency comprises a measurable difference between an amount of sunlight input at said at least one focusing element and an amount of sunlight output from said at least one focusing element and the second optical efficiency comprises a measurable difference between an amount of sunlight input at said least one light guide and an amount of sunlight output from said at least one light guide; each third optical efficiency is dependent on the first optical efficiency and the second optical efficiency; and/or adjusting the output voltage and current of each of the photovoltaic cells in the array comprises sensing an output current and an output voltage of each said photovoltaic cell, and locking one of the output current or output voltage to the maximum power point.

In yet another embodiment there is provided a solar panel comprising any one of the sunlight concentration photovoltaic apparatuses described above.

The embodiments herein thus provide a CPV apparatus including a plurality of optical concentrators, wherein the plurality of optical concentrators is coupled to the PV cells. Any number of PV cells may be included. A novel integrated power efficiency optimizer (IPEO) is provided for each PV cell to reduce loss of output power of the plurality of the photovoltaic cells and to convert power on a single PV cell base. In this way a constant voltage or current output may be generated by each PV cell subject to internal and/or external conditions otherwise affecting the performance of the concentrators and PV cells.

In some embodiments, the CPV apparatus may be arranged as a solar PV panel and may include several modules each comprising an optical concentrator, a PV cell and an IPEO, each module operating separately to provide a maximum total power output of the solar PV panel that is generally independent from inherent fluctuations in the individual performance or efficiency of each optical concentrator or PV cell. In some embodiments, the output optical efficiency of each concentrator may be affected by variations in one or more of the following non-exhaustive environmental factors: shading, dust, tracking errors, and snow. Also, in some embodiments, the output optical efficiency of each optical concentrator may be affected by anomalies or variations in one or more of the following non-exhaustive factors: optical transmission, optical or material absorption, change in the refractive index, coefficient of reflection, surface damage, fogging, relative angular or lateral misalignment, bending or other change in shape of surface, and defocus.

In some embodiments, any type of known single junction or multiple junction PV cell can be used in conjunction with the concentrators and IPEOs.

A single concentrating solar PV panel according to the embodiments described herein may be used, or a number of concentrating solar PV panels may be used in a solar farm or other environment.

In some embodiments, the ratio between the number of concentrators and the number of PV cells in a single concentrating solar PV panel is selected depending on its intended application. Further, in each concentrating solar PV panel, each IPEO may be connected to a single corresponding PV cell, whereas in other embodiments, one IPEO may be connected to several corresponding PV cells.

In some embodiments, the IPEO is provided for the CPV module as a system on chip (SoC). Also, in some embodiments, the IPEO is attached to an IPEO support located in a plane under the concentrator of the CPV module. In other embodiments, where the IPEO may be attached to an IPEO support located in the same plane as the PV cell.

The optical concentrator used in the solar PV panel may be of any known and practical type, such as reflective, refractive, diffractive, Total Internal Reflection (TIR) waveguides and luminescence optics. The panel may also be provided with a single-axis or double-axis solar tracking system. In other embodiments, the panel may include an optical tracking system coupled to each concentrator.

The degree of concentration for each CPV module may be selected to have a low range (e.g. 2-20×), medium range (e.g. 20-100×), or high range (e.g. 100-1000×). In some embodiments, each optical concentrator comprises a single optical component. In other embodiments, each optical concentrator comprises several optical components.

Embodiments of the present invention may have one or more of the above-mentioned aspects, but do not necessarily comprise all of the above-mentioned aspects or objects described herein, whether express or implied. It will be understood by those skilled in the art that some aspects of the embodiments described herein may have resulted from attempting to attain objects implicitly or expressly described herein, but may not satisfy these express or implied objects, and may instead attain objects not specifically recited or implied herein.

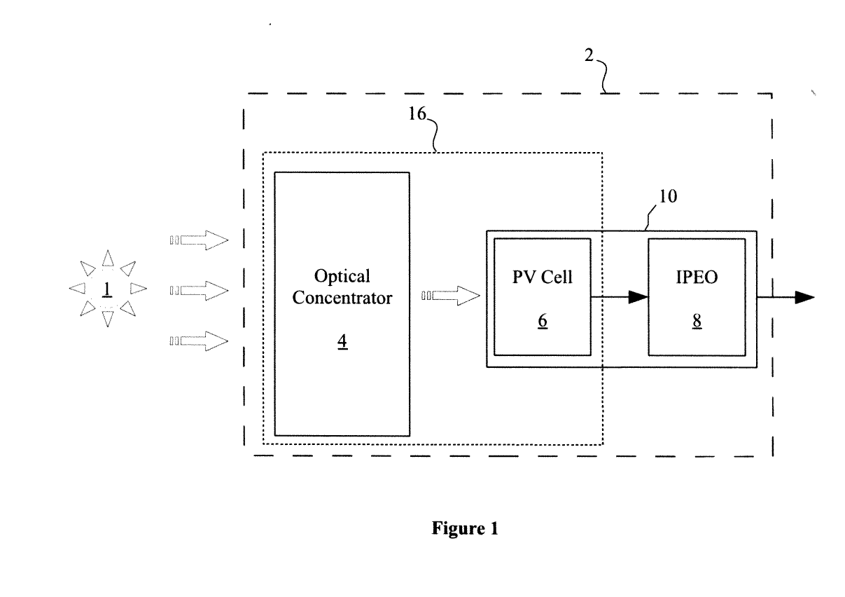

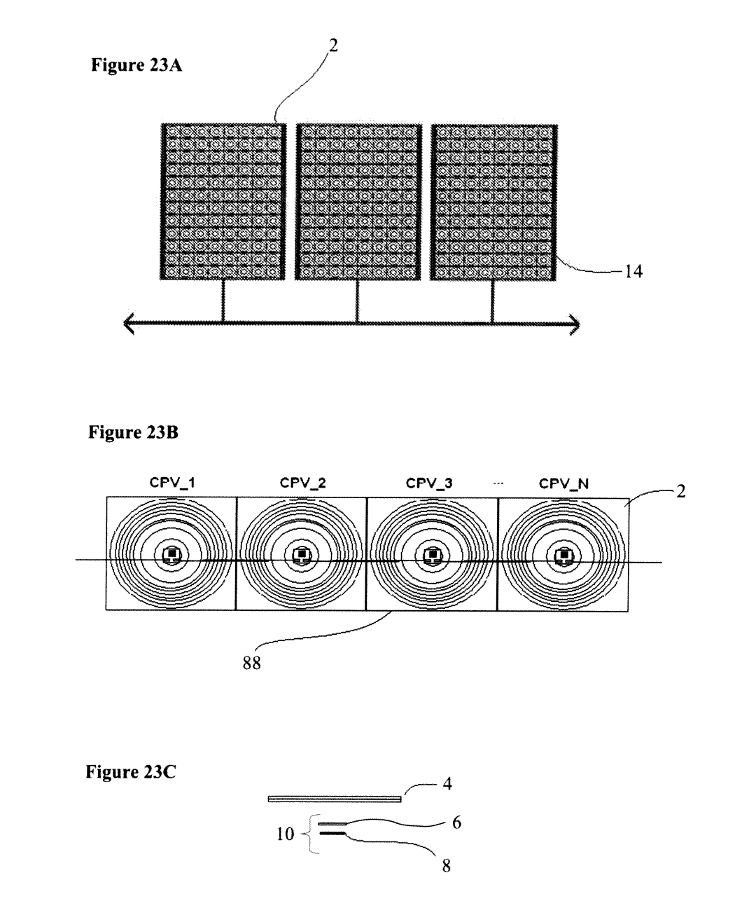

FIGS. 1 and 23C illustrate an integrated CPV module 2 of the type that may be used with the embodiments described herein. The integrated CPV module 2 generally comprises an optical module 16, which in turn comprises a sunlight optical concentrator 4 and a PV cell 6 optically coupled to the optical concentrator 4 to receive concentrated sunlight therefrom. In the integrated CPV module 2, the PV cell 6 itself is integrated in a sunlight receiver assembly 10 in electrical communication with an integrated power efficiency optimizer (IPEO) 8.

Optical concentrators generally comprise one or more optical elements for the collection and concentration of light, such as focusing elements including lenses and mirrors, light- or waveguides, and other optically concentrative devices retained in a fixed spatial position relative to the PV cell and optically coupled to an active surface of the PV cell. Examples of optical elements include Winston cones, Fresnel lenses, a combination of a lens and secondary optics, total internal reflection waveguides, luminescent solar concentrators and mirrors.

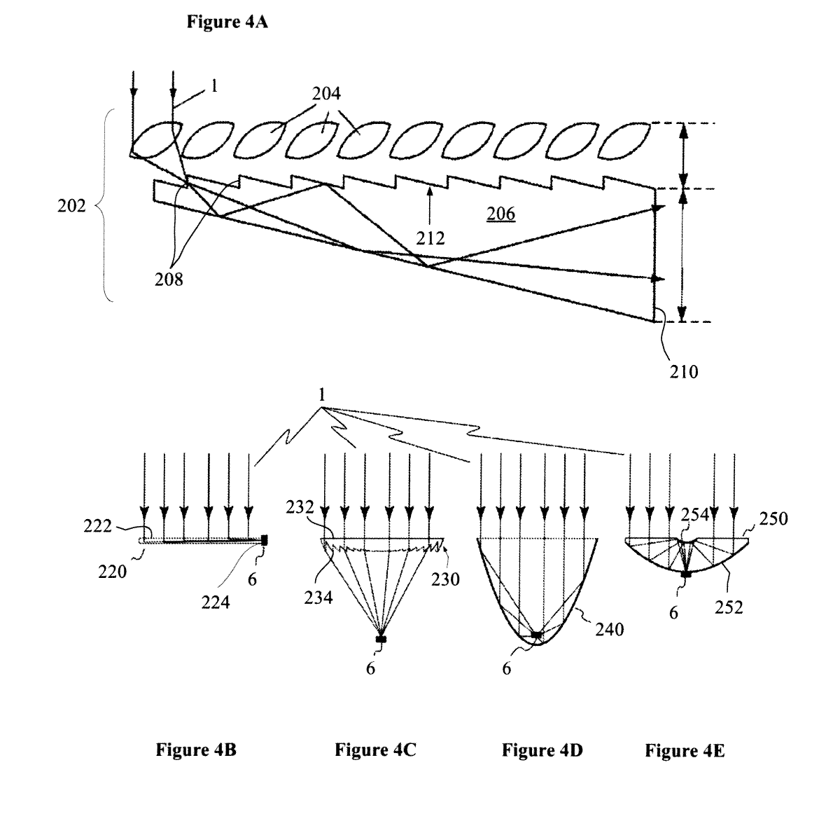

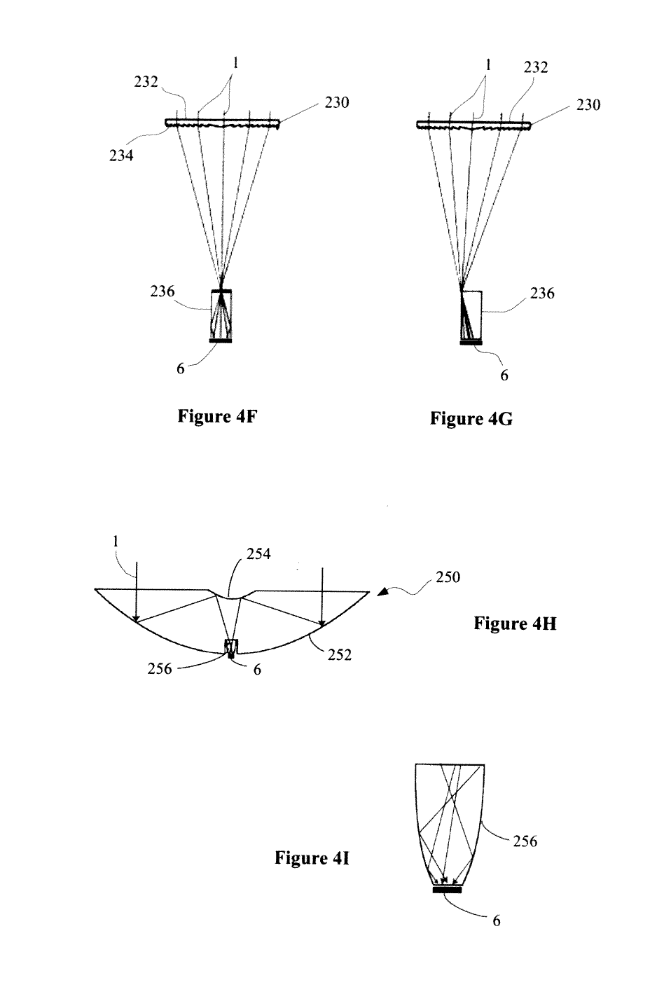

The optical concentrator of the integrated CPV module 2 may comprise a single optical element or several optical elements for collecting, concentrating and redirecting incident light on the PV cell 6. Examples of single-optic assemblies are illustrated in FIGS. 4B-4D. The optical concentrator 220 of FIG. 4B comprises a total internal reflection waveguide that accepts light incident upon one or more surfaces 222 of the waveguide and guides the light by total internal reflection to a PV cell 6 at an exit surface 224. The optical concentrator 230 of FIG. 4C comprises a Fresnel lens which redirects light incident upon a first surface 232 toward a PV cell 6 maintained in fixed relation to a second surface 234 of the Fresnel lens 230 opposite the first surface 232. The optical concentrator 240 of FIG. 4D is a parabolic reflector in which a PV cell is maintained at the focal point of the reflector.

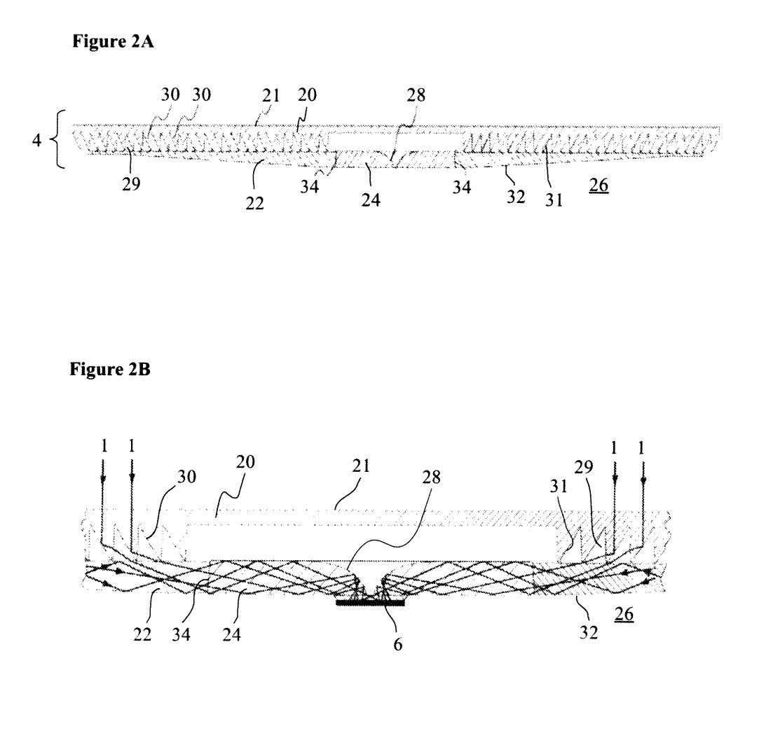

Embodiments of multiple-optic assemblies are described below with reference to FIGS. 2A, 2B, 3, 4E-4I, 5A and 5B and in United States Patent Application Publication No. 2008/0271776, filed May 1, 2008, titled “Light-Guide Solar Panel And Method Of Fabrication Thereof”, United States Patent Application Publication No. 2011/0011449, filed Feb. 12, 2010, titled “Light-Guide Solar Panel And Method Of Fabrication Thereof”, U.S. Provisional Patent Application No. 61/298,460, filed Jan. 26, 2010, titled “Stimulated Emission Luminescent Light-Guide Solar Concentrators”, the entireties of which are incorporated herein by reference.

The sunlight concentration unit 250 of FIG. 4E comprises a primary optic 252 and a secondary optic 254. The primary optic 252 may be a dome-shaped reflector that reflects incident light toward a secondary optic 254. In turn, the secondary optic 254 reflects the light toward a PV cell 6 mounted to the base of the dome.

Optical concentrators 4 comprising a focusing element that focuses the sunlight into a light beam, such as those in the examples of FIGS. 4F, 4G and 4H, may further comprise a relatively small light guide 236 and 256. The light guide 236 and 256 is located in the focal plane of the focusing element and is optically coupled to the focusing element 230, 250 to further guide the light toward the PV cell 6 as shown in FIGS. 4F, 4G and 4I.

Referring to FIGS. 2A and 2B, the optical concentrator 4 may include a primary optic, which here comprises a focusing element or light insertion stage 20 and an optical waveguide stage 22, and a secondary optic 24. The light insertion stage 20 and the optical waveguide stage 22 may each be made of any suitable optically transmissive material. Examples of suitable materials can include any type of polymer or acrylic glass such as poly(methyl-methacrylate) (PMMA), which has a refractive index of about 1.49 for the visible part of the optical spectrum.

The light insertion stage 20 receives sunlight 1 impinging a surface 21 of the light insertion stage 20, and guides the sunlight 1 toward optical elements such as reflectors 30, which preferably directs the incident sunlight by total internal reflection into the optical waveguide or light guide stage 22. The reflectors 30 may be defined by interfaces or boundaries 29 between the optically transmissive material of the light insertion stage 20 and the second medium 31 adjacent each boundary 29. The second medium 31 may comprise air or any suitable gas, although other materials of suitable refractive index may be selected. The angle of the boundaries 29 with respect to impinging sunlight 1 and the ratio of the refractive index of the optically transmissive material of the light insertion stage 20 to the refractive index of the second medium 31 may be chosen such that the impinging sunlight 1 undergoes substantially total internal reflection or total internal reflection. The angle of the boundaries 29 with respect to the impinging sunlight 1 may range from the critical angle to 90°, as measured from a surface normal to the boundary 29. For example, for a PMMA-air interface, the angle may range from about 42.5° to 90°. The reflectors 30 thus defined may be shaped like parabolic reflectors, but may also have any suitable shape.

As illustrated in FIG. 2B, the sunlight then propagates in the optical waveguide stage 22 towards a boundary 32, angled such that the sunlight 1 impinging thereon again undergoes total internal reflection, due to the further medium 26 adjacent the boundary 32 of the optical waveguide stage 22. The sunlight 1 then propagates toward a surface adjacent the light insertion stage 20 at which it again undergoes total internal reflection or substantially total internal reflection. The sunlight 1 continues to propagate by successive internal reflections through the optical waveguide stage 22 toward an output interface 34 positioned “downstream” from the sunlight's entry point into the optical waveguide stage 22. In an embodiment of the optical concentrator 4 shaped in a substantially square or circular form, with substantially circular concentric reflectors 30 disposed throughout the light insertion stage 20, the output interface 34 may be defined as an aperture at the centre of the concentrator 4.

The sunlight then exits the optical waveguide stage 22 at the output interface 34 and enters the secondary optic 24, which is a second focusing element 24 and is in optical communication with the output interface 34 and directs and focuses the sunlight onto an active surface of a PV cell (not shown in FIG. 2). The secondary optic may comprise a parabolic coupling mirror 28 to direct incident light towards the PV cell. The PV cell may be aligned with the secondary optic 24 so as to receive the focused sunlight at or near a center point of the cell. The secondary optic 24 may also provide thermal insulation between the optical waveguide stage 22 and the PV cell 6.

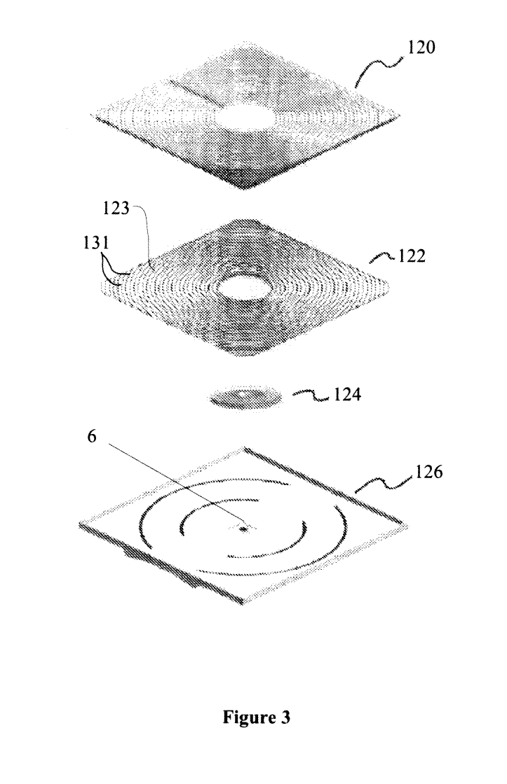

In the embodiment illustrated in FIG. 3, a light insertion stage 120 and a optical waveguide stage 122 that are similar to the light insertion stage 20 and optical waveguide 22 of FIG. 2 are mountable with the secondary optic 124 that is similar to secondary optic 24 of FIG. 2, in a tray 126, which provides support to the substantially planar stages 120, 122 as well as to the secondary optic 124 and the PV cell 6. The second medium 131 may be the material of the optical waveguide stage 122 and may be integral to the optical waveguide stage 122, forming ridges on the surface 123 of the optical waveguide stage 122 adjacent the insertion stage 120. The light insertion stage 120, the optical waveguide stage 122 and the secondary optic 124 are otherwise as described above in reference to FIGS. 2A and 2B. The PV cell 6 may be fixedly mounted to the tray 126 so as to maintain its alignment with the secondary optic 124. The tray 126 may be formed of a similar optical transmissive medium as the stages 120, 122, and may include means for mounting on a solar panel.

In another embodiment, the optical concentrator 202 in FIG. 4A described in United States Patent Application Publication No. 2008/0271776, filed May 1, 2008, comprises a series of lenses 204 disposed in a fixed relation to a waveguide 206. Incident light 1 is focused by the lenses 204 onto interfaces 208 provided at a surface 212 of the waveguide 206, and are redirected through total internal reflection towards an exit interface 210, and optionally propagated through further optics before focusing and concentrating the light 1 on a PV cell (not shown).

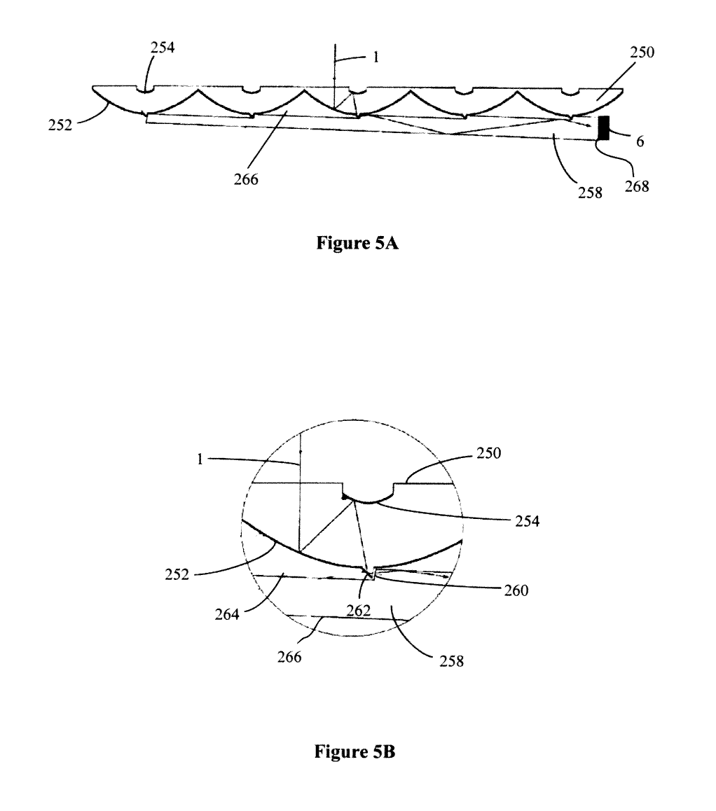

Alternatively, as illustrated in FIGS. 5A and 5B, a plurality of sunlight concentration units 250 may be provided as a light insertion stage, wherein instead of having a PV cell mounted to the base of the dome, a reflector 262 is provided to direct light into a light guide 258 at a light insertion surface 260 of the light guide 258. The sunlight 1 then propagates in the light guide 258 towards a surface 264 facing the light insertion stage, angled such that the sunlight 1 impinging thereon again undergoes total internal reflection. The sunlight 1 then propagates toward a boundary 266 at which it again undergoes total internal reflection or substantially total internal reflection. The sunlight 1 continues to propagate by successive internal reflections through the light guide 258 toward an output surface 268 positioned “downstream” from the sunlight's entry point into the light guide 258. Concentrated sunlight is thus directed onto a PV cell 6 positioned at the output surface 268 of the light guide 258.

Focusing elements may thus be refractive optical elements as in the examples of FIGS. 2A, 2B, 3, 4A, 4C and 4F or may be reflective optical elements such as in the examples of FIGS. 4D, 4E, 4H, 5A and 5B.

As will be appreciated by those skilled in the art, the optical concentrator used may be of any known and practical type. Other examples of types of optical concentrators 4 that may be used include Winston cones and luminescent solar concentrators.

The degree of concentration to be achieved by the optical concentrator 4 is selected based on a variety of factors known in the art. The degree of concentration may be in a low range (e.g., 2-20 suns), a medium range (e.g., 20-100 suns) or a high range (e.g., 100 suns and higher).

In many of the foregoing embodiments, the PV cell 6 may be integrated with the optical concentrator 4 to provide an optical module 16 that is easy to assemble, as in the example of FIG. 3. The PV cell 6 may be a multi-junction cell (such as a double-junction or triple-junction cell) to improve absorption of incident sunlight across a range of frequencies, although a single-junction cell may also be used. The PV cell 6 may have a single or multiple active surfaces. In some embodiments, positive and negative contacts on the solar cell are electrically connected to conductor traces by jumper wires, as described in further detail below.

The efficiency of an optical module 16 such as that described above is generally determined by the efficiencies of the optical concentrator 4 and the PV cell 6. Generally, the PV cell 6 is characterized by a photovoltaic efficiency that combines a quantum efficiency and by its electrical efficiency. The optical concentrator is characterized by an optical efficiency.

The efficiency of both components is dependent on both internal and external factors, and the efficiency of the optical module 16 as a whole may be affected by still further factors. In the case of the optical concentrator, design, manufacturing and material errors, and operating and environmental conditions may result in the degradation of the concentrator and of the module as a whole. For example, point defects in the one or more optical elements of the concentrator, which may be introduced during manufacture, will reduce the efficiency of the concentrator. Each optical element therefore has at least a given optical efficiency, which may comprise a measurable difference between an amount of sunlight input at the optical element and an amount of sunlight output from the optical element. In an embodiment of a multi-optic concentrator comprising one or more focusing elements and one or more light guides, each focusing element will have a first optical efficiency and each light guide will have a second optical efficiency. In an optic concentrator having a single optic element, a single optical efficiency may be associated therewith.

Angular or lateral misalignments of the optical elements, which may be introduced during manufacture, shipping, or even in the field, will also affect the optical efficiency of the concentrator as a whole. Even without external influences, transmission losses may be suffered due to factors such as mirror reflectivity, absorption, and Fresnel reflection. In the case of a multiple-optic concentrator 4, the misalignments of the optical elements and other factors contribute to a third optical efficiency of the optical concentrator 4.

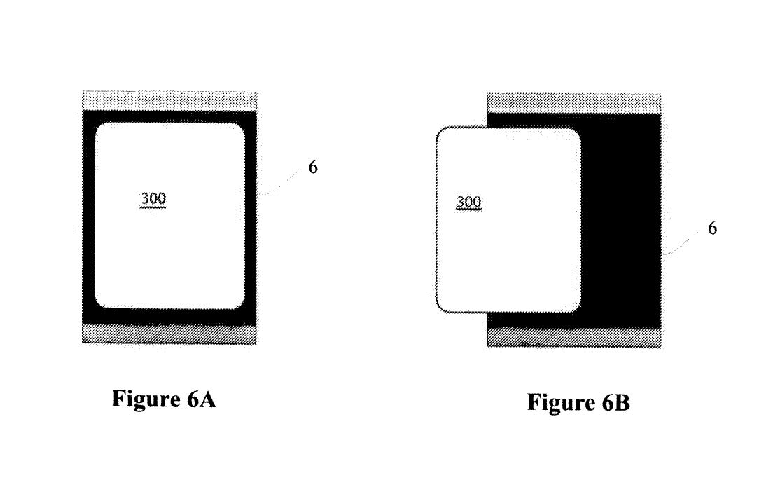

Within the optical module 16 itself, misalignment between the concentrator 4 and the PV cell 6 may result in misdirection of the focused light 300 on the PV cell 6 away from the most responsive central region of the PV cell 6 (as shown in FIGS. 4F and 6A) and towards an edge, as illustrated in FIGS. 4G and 6B. Such misalignment between the concentrator 4 and the PV cell 6 may also affect the third optical efficiency of a multiple-optic concentrator 4, or introduce a further optical efficiency of a single-optic concentrator 4. Misdirection may also be introduced where a solar tracking system used with the optical module 16 fails. Further, with regard to all components, aging and environmental conditions such as dust, fogging, and snow may generally adversely affect the component materials and lead to performance degradation over time.

Design, manufacturing, material errors related to the focusing elements and the waveguides that determine the optical efficiency of each of them may be compounded and may contribute to the errors of the optical concentrator 4. The second optical efficiency of a single-optic concentrator 4 may therefore be dependent on the first optical efficiency. Similarly, the third optical efficiency of a multi-optic concentrator 4 may be dependent on the first optical efficiencies and/or the second optical efficiencies of its constituent optical elements (which in the embodiment described above are focusing elements and light guides).

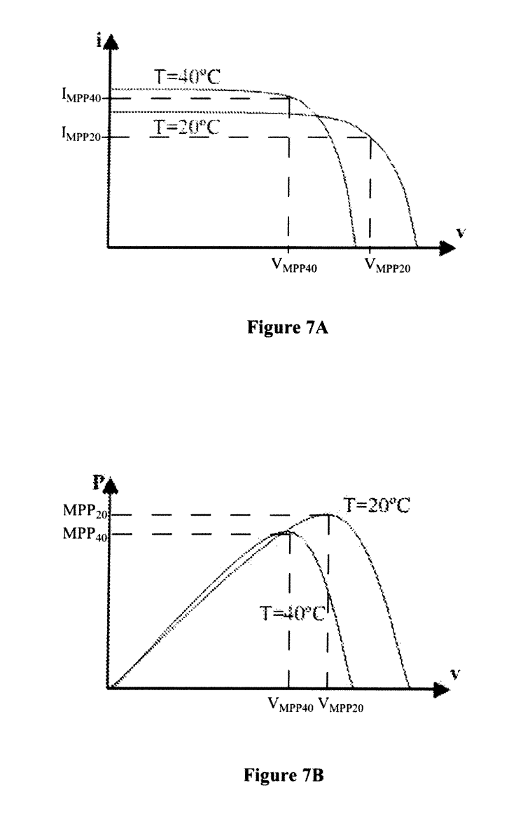

Further, variations in the manufacture and performance of the PV cell 6 itself may adversely affect efficiency. FIGS. 7A and 7B illustrate how the output current-output voltage characteristic (I-V curve) and output power-output voltage characteristic (P-V curve) of a solar cell, respectively, may vary at different operating temperatures. It is known that PV cells each have their own optimum operating point, called the maximum power point (MPP=I_{MPP}·V_{MPP}), that is highly dependent on the temperature and incident light on the PV cell and varies with age. Assemblies of PV cells also have an MPP that is dependent on the MPPs of its constituent PV cells.

In summary, numerous factors, both internal and environmental may adversely effect the overall efficiency of any CPV module and may create a range of optical efficiencies among concentrators 4 assembled in a string 88, a solar panel 14 or an array. If the efficiency of optical concentrators within a solar panel 14 is not matched, the performance of the panel or array will be downgraded to the level of the lowest performing optical module. While some of these factors are controllable or at least manageable through binning and sorting at the manufacturing stage as mentioned above, there is still the possibility that further mismatches will be introduced during the shipping or installation process, or even during field use, where further binning or sorting may not be practical. Even the performance of a string or array of initially well-matched modules may be degraded due to variations or defects introduced after manufacture. Therefore, optical efficiencies of the optical elements and the concentrator as a whole generally vary over time.

To address at least some of these possible deficiencies, power conditioners such as DC-DC converters may be designed to track the MPP of a solar panel or string of PV cells. Such tools are known as Maximum Power Point Trackers (MPPTs). Power conditioners including MPPTs are typically located in the connection or junction box of the solar panel. Finding power conditioners such as MPPTs or inverters that can match varying output power from solar panels is extremely difficult, time consuming and costly; in some cases there may not be means available to convert such irregular power levels. In the case of PV cell mismatch, the output power will differ greatly amongst solar panels, thus requiring different power conditioners to match the output of each individual solar panel or MPPT.

Thus, in an embodiment of the integrated CPV module 2 as shown in FIG. 1, a receiver assembly 10 is provided with both the PV cell 6 and an IPEO 8 for providing, simultaneously, adjustment of the output voltage and current of the PV cell to reduce loss of output power of multiple photovoltaic cells resulting from differences amongst the second optical efficiencies of the optical concentrators and power conversion of the PV cell output power. The IPEO 8 may therefore lock the output of the optical module to a constant voltage and/or constant current—the MPP voltage, V_{MPP}, and/or MPP current, I_{MPP}—thereby substantially reducing or eliminating undesirable effects of variations in the optical efficiency and/or photovoltaic efficiency of the concentrator 4 or PV cell 6, on a cell-by-cell basis. By providing PV-cell level optimization in this manner, the impact of variations between individual optical modules 16 in panels, strings or arrays comprising multiple modules 16 caused by pre- or post-manufacturing, shipping, installation or field use incidents will be reduced, thereby improving the overall performance of the panels, strings or arrays.

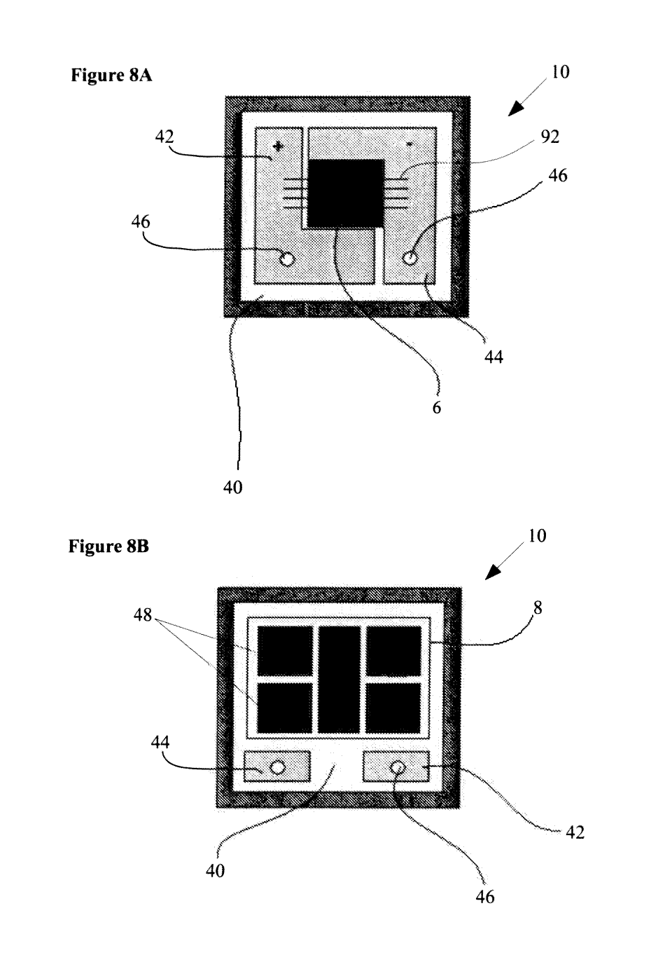

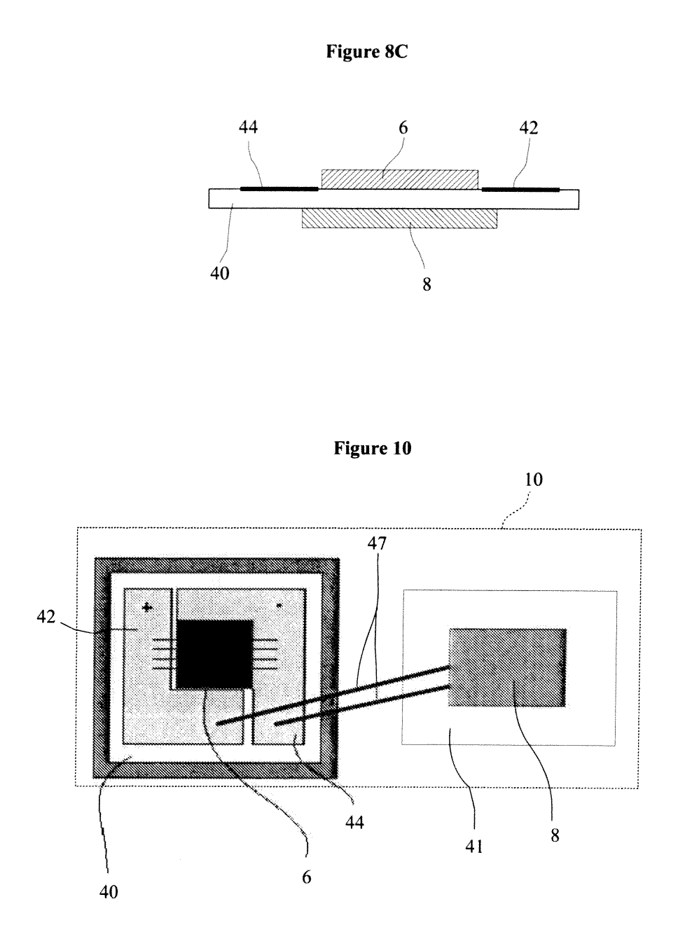

The receiver assembly 10 may be compactly and conveniently provided in a single integrated assembly. Referring to FIG. 8A, the receiver assembly 10 may be provided on a printed circuit board. In one embodiment, a PV cell 6 is affixed to a substrate 40 of the circuit board and electrically connected at its positive and negative contacts 90 by jumper wires 92 to positive and negative conductor traces 42, 44 printed on the substrate 40. The substrate 40 also supports the IPEO 8 which is in electrical communication with the PV cell 6. The receiver assembly 10 may also have vias 46. In this form, the receiver assembly 10 may be supported, for example, in the tray 126 of the optical module illustrated in FIG. 3, sandwiched between the optical components of the concentrator illustrated in FIG. 4, or mounted in relation to the various concentrators shown in FIGS. 4A through 4H.

The IPEO 8 may thus provide MPPT and power conversion for a single PV cell 6 of the same receiver assembly 10 on which the IPEO 8 is provided. In one embodiment, the IPEO 8 comprises control circuitry or a system-on-a-chip (SoC) controller to implement MPPT. In the embodiment of FIG. 8A, the PV cell 6 is affixed to a first face of the substrate 40, although in other embodiments, such as that shown in FIGS. 8B and 8C, the IPEO 8 can be affixed to a second face of the substrate 40 opposite the face on which the PV cell 6 is mounted. In these embodiments, the IPEO 8 comprises dedicated control circuitry implemented with several integrated circuit (IC) chips 48 and/or passive components such as heat sinks (not shown) to provide a robust controller. This embodiment also provides two vias 46; one via 46 through each of the conductor traces 42, 44.

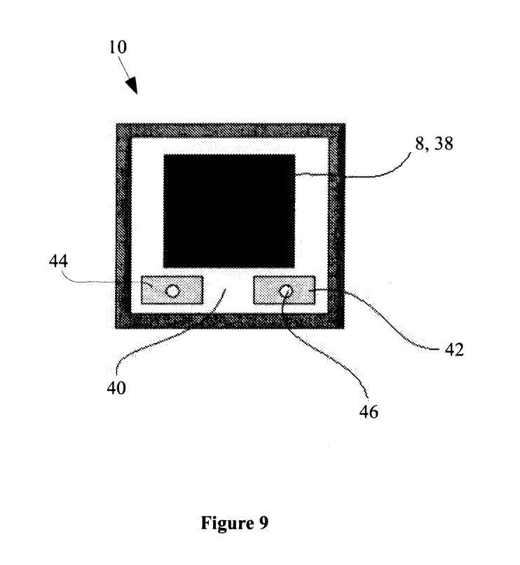

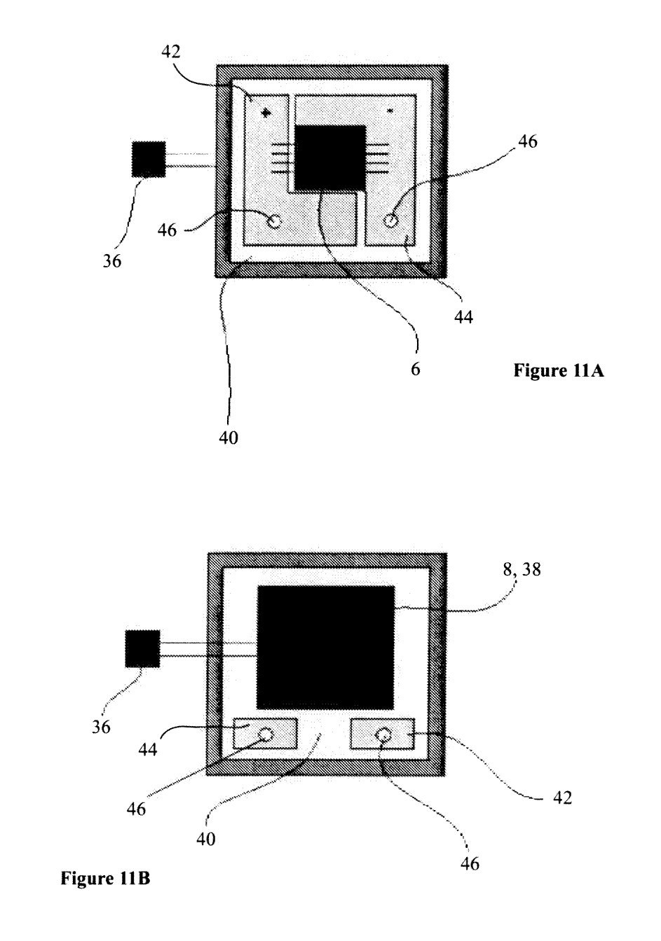

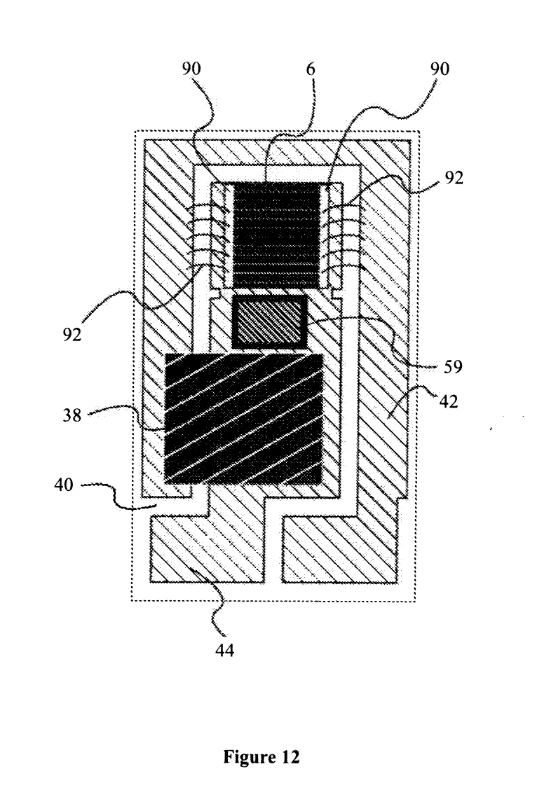

In an alternate embodiment shown in FIGS. 9 and 12, the receiver assembly 10 is substantially similar to that shown in FIGS. 8A and 8B, except that the IPEO 8 comprises a single SoC 38 and may also comprise passive components (not shown). The SoC 38 may be a microcontroller. Use of an SoC 38 may reduce cost and facilitate manufacture of the integrated CPV module.

In other embodiments, such as that shown in FIG. 10, the IPEO 8 may be mounted on a separate printed circuit board 41 that forms part of the receiver assembly 10. The IPEO 8 is in electrical communication with the PV cell 6 via leads 47.

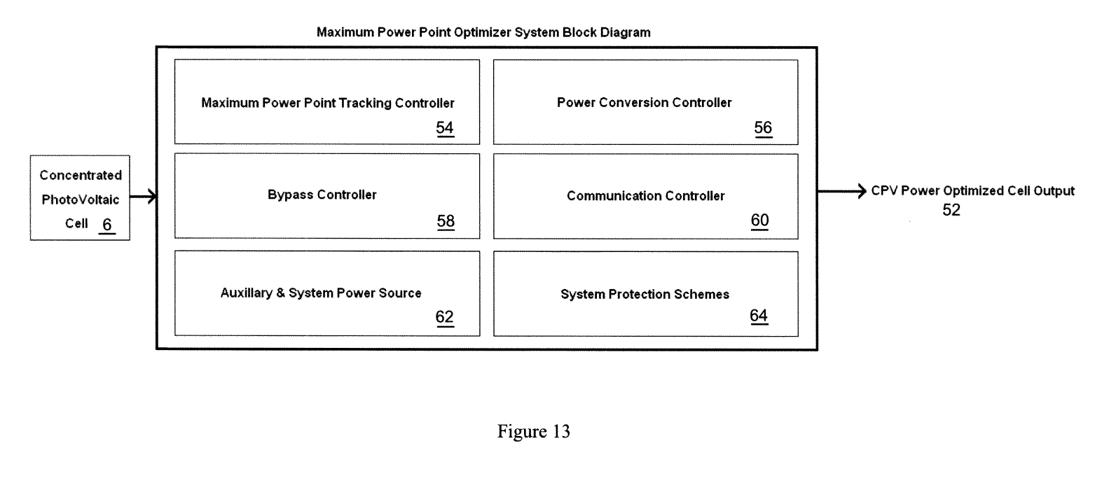

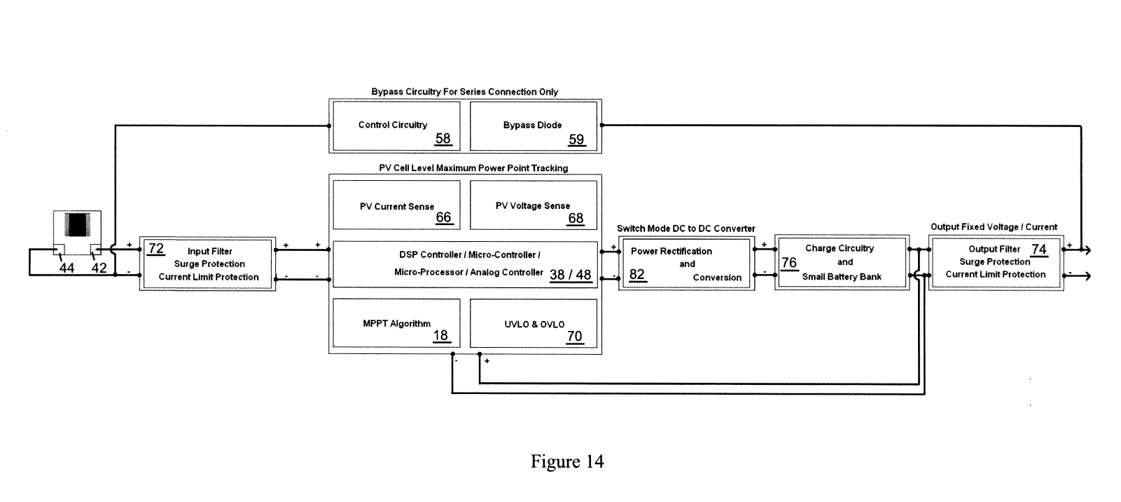

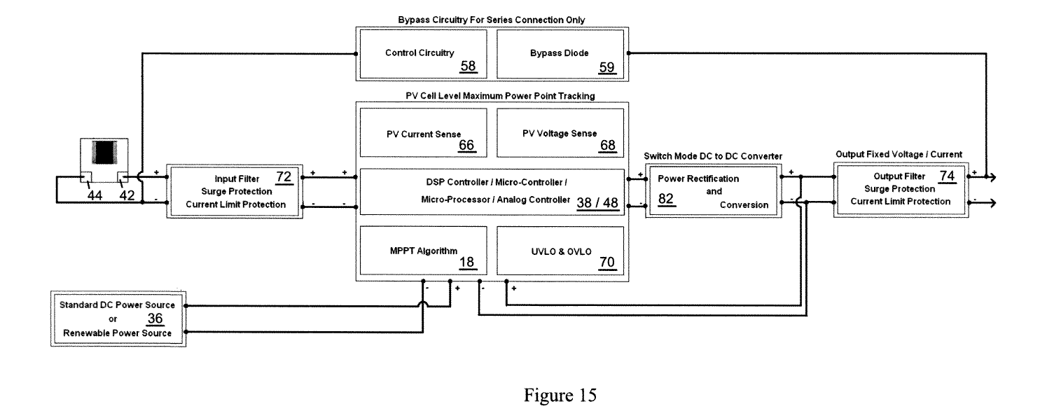

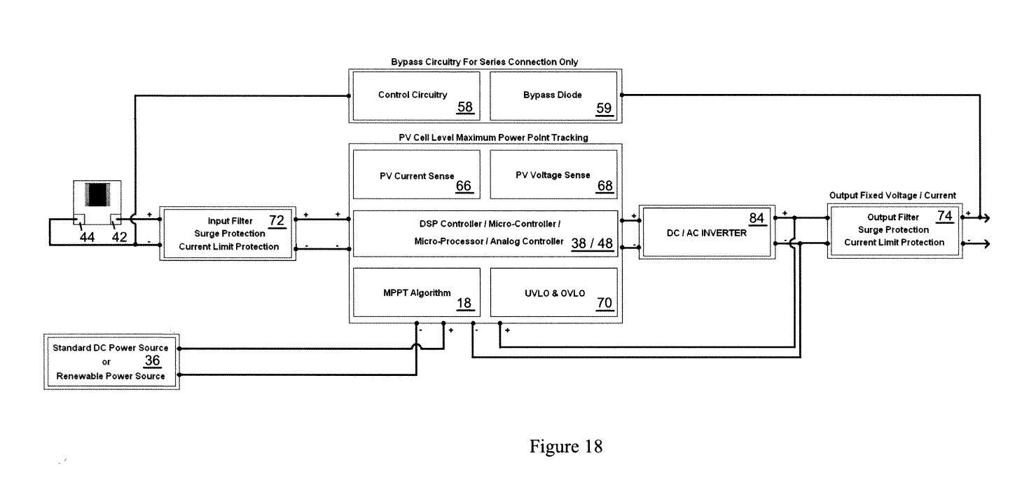

The IPEO 8 receives electrical power transmitted from the PV cell 6, tracks the MPP of the optical module 16 and converts the input power 50 to either a constant current or a constant voltage power supply 52. The IPEO 8 system therefore comprises an MPPT controller 54 and a power conversion controller 56, and may also comprise a bypass controller 58, a communication controller 60, system protection schemes 64 and/or an auxiliary power source 62, as shown in FIG. 13. Examples of circuit configurations that may be used to implement IPEOs 8 are shown in the block diagrams of FIGS. 14 to 18.

The MPPT controller 54 tracks the MPP by sensing the input voltage and current using sensors 66, 68 and analysing the input voltage and current from the PV cell, and locks the input voltage and current to the optical module's MPP. Any appropriate MPPT control algorithm 18 may be used. Examples of MPPT control algorithms include: perturb and observe, incremental conductance, constant voltage, and current feedback.

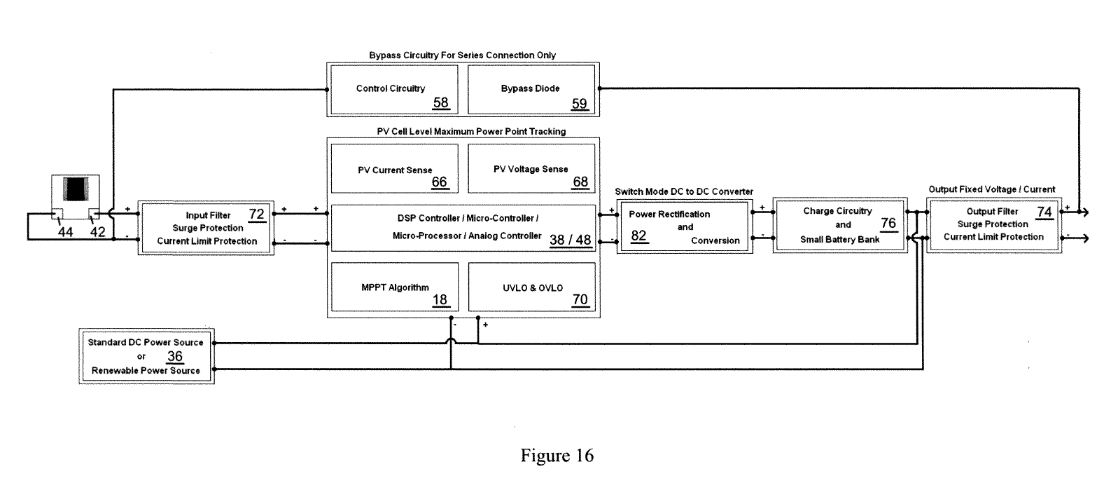

The power conversion controller 56 may comprise a rectifier and DC/DC converter 82 to convert a variable non-constant current and a non-constant voltage input to a constant voltage or constant current for supply to an electrical bus. Alternatively, the power conversion controller 56 may comprise an AC/DC inverter 84 to convert the direct current (DC) output into alternating current (AC), as shown in FIG. 16.

In embodiments with one or more bypass diodes 59 for serial connection of integrated CPV modules, the bypass controller 58 controls the bypass diodes 59. A bypass diode 59 is enabled when the optical module 16 produces too little power to be converted.

Any power source can power the active components on the receiver assembly 10. In one embodiment, an auxiliary power source, such as one or more batteries 76, can be used to power the active components of the receiver assembly 10. To take advantage of the optical elements of the integrated CPV module, the batteries 76 may be charged by solar power from one or more secondary PV cells 36 (as shown in FIGS. 11A and 11B) converted into electricity. Alternatively, the batteries 76 may be charged by the power bus of the system. One or more of the batteries 76 may be an on-board battery and the secondary PV cells 36 can be placed to capture diffused light under the primary or secondary optics of the optical concentrator 4. The auxiliary power source 62 may include an auxiliary power controller to control the supply of power to the chips 48 or SoC 38 from an on-board battery, an electrical power bus and/or directly from a secondary PV cell 36.

The system protection schemes 64 may include undervoltage-lockout (UVLO) and overvoltage-lockout (OVLO) circuitry 70, input and output filters for surge and current limit protection 72, 74.

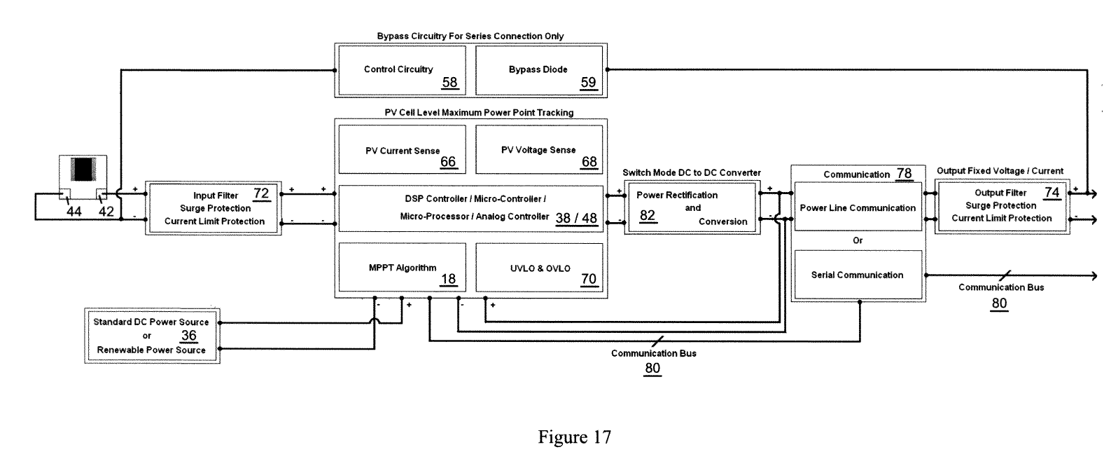

The IPEO 8 may also have communication circuitry 78 comprising a communication controller 60 and a communication bus 80 (an embodiment of which is shown in FIG. 17) for communication of control signals and data internal to the IPEO 8, with other integrated CPV modules and/or a central controller. The data communicated may include measurement data such as performance indicators and power generated.

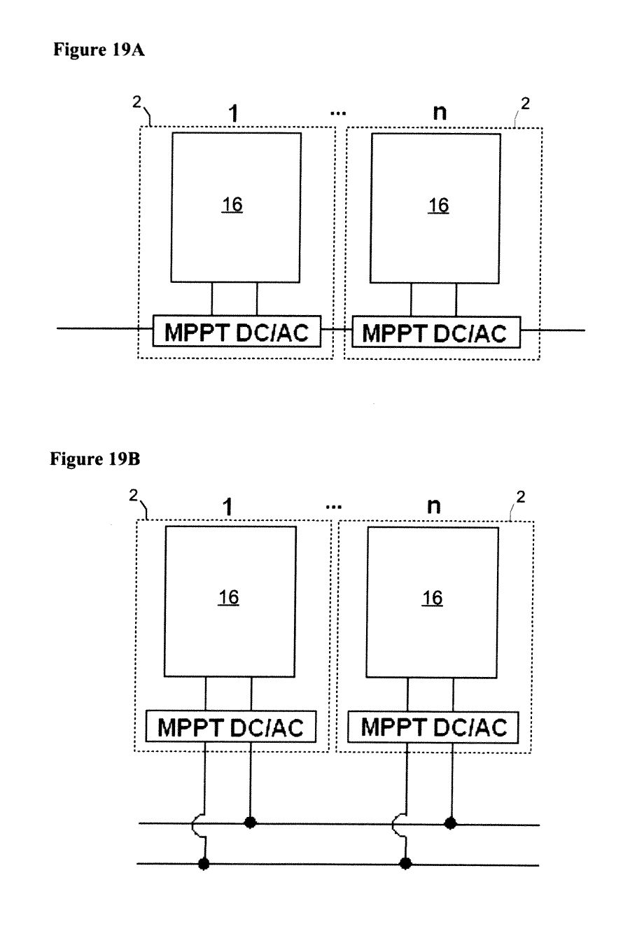

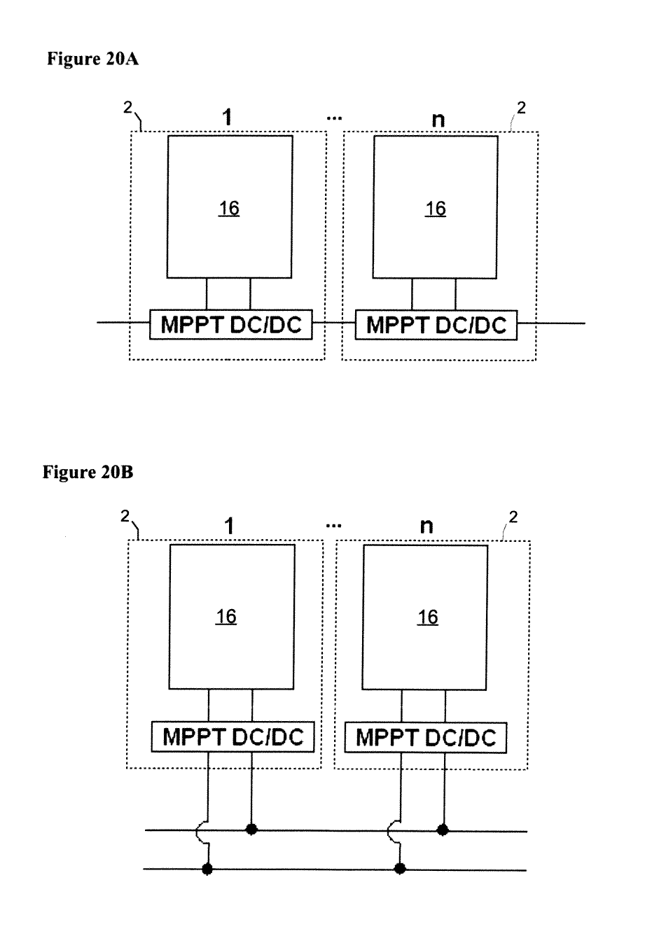

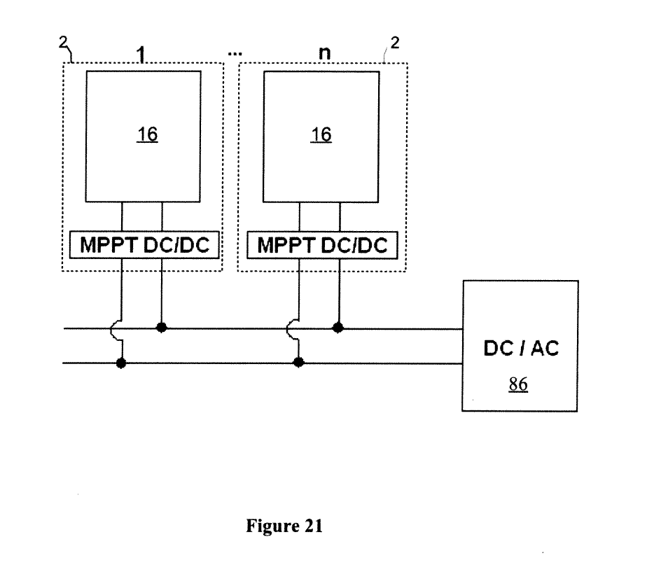

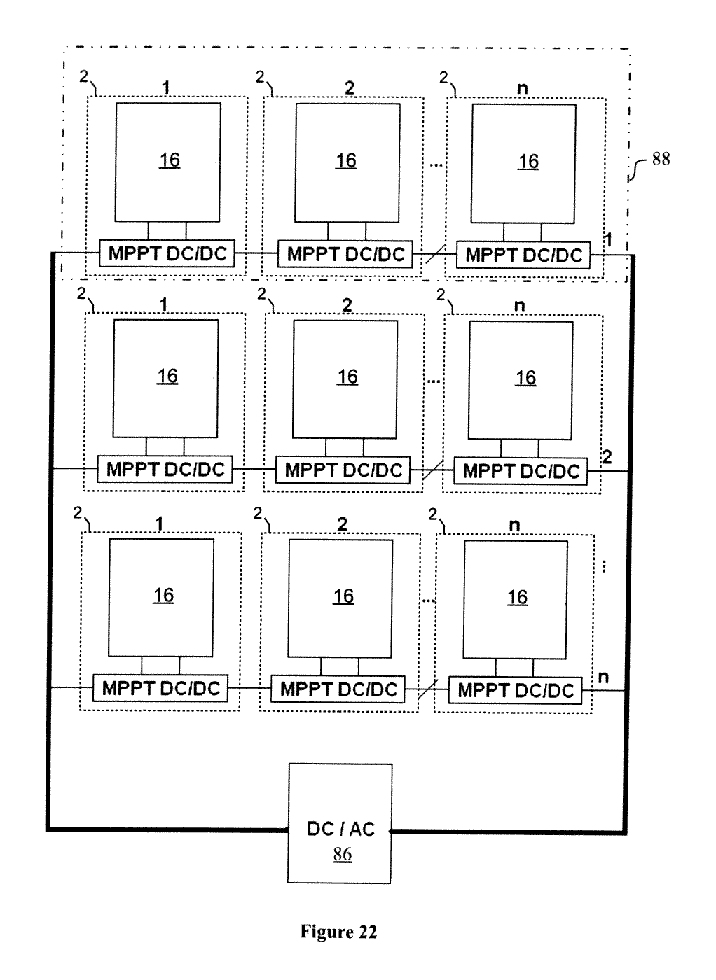

Integrated CPV modules 2 may be connected in series as illustrated in FIGS. 19A, 20A and 23B or in parallel as illustrated in FIGS. 19B and 20B. As shown in FIG. 22, strings 88 of integrated CPV modules 2 connected in series may also be connected in parallel with other strings 88 to form a matrix or array of integrated CPV modules 2, as shown in FIG. 19. The power harnessed by interconnected integrated CPV modules 2 with DC output at a first stage may be converted to AC using a DC/AC inverter 86 at a second stage of conversion, as shown in FIGS. 21 and 22.

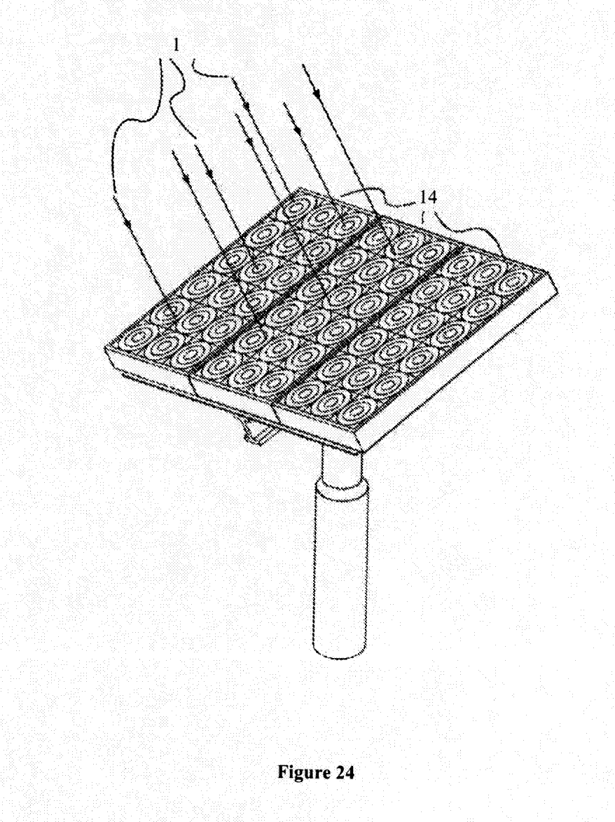

A solar panel 14 may comprise an array of interconnected integrated CPV modules 2 as illustrated in FIGS. 23A and 24. The solar panel 14 may comprise any number of integrated PV modules 2. In fact, not all PV cells 6 of a solar panel 14 need be coupled with an optical concentrator 4. The ratio between the number of optical concentrators 4 and the number of PV cells 6 on a given solar panel 14 is selected based on its application. In some embodiments, each PV cell 6 is connected to an IPEO 8. In other embodiments, several optical modules 16 or PV cells 6 may be connected to a single IPEO such that the solar panel 14 has fewer IPEOs 8 than PV cells 6. However, the later embodiments will not achieve the optimal performance of a solar panel 14 though they will likely be less expensive to manufacture.

A solar panel 14 comprising integrated CPV modules 2 may be attached to a solar tracking system of one or more axes. Additionally or alternatively, the solar panel 14 may comprise a solar tracking system coupled to each optical concentrator.

A solar panel 14 comprising integrated CPV modules 2 may work alone, or in conjunction with several other solar panels, as shown in FIG. 23A, in a solar farm or other environments. The other solar panels may or may not comprise integrated CPV modules 2.

It will be apparent to those skilled in the art that although the many of the embodiments described herein comprise an optical concentrator 4, the receiver assembly 10 can work without a concentrator optically coupled to the PV cell 6.

Various embodiments of the present invention having been thus described in detail by way of example, it will be apparent to those skilled in the art that variations and modifications may be made without departing from the invention. The invention includes all such variations and modifications as fall within the scope of the appended claims.

What is claimed is:

1. A sunlight concentration photovoltaic apparatus comprising:
a plurality of optical concentrators adapted to receive input sunlight, each optical concentrator comprising at least one focusing element having a first optical efficiency and at least one light guide having a second optical efficiency, the at least one light guide being optically coupled to the at least one focusing element, each one of the plurality of optical concentrators having a corresponding third optical efficiency;
a plurality of sunlight receiver assemblies, each sunlight receiver assembly comprising a photovoltaic cell arranged to receive sunlight output from a corresponding one of the plurality of optical concentrators and an integrated power efficiency optimizer in electrical communication with said photovoltaic cell, the integrated power efficiency optimizer being configured to adjust an output voltage and current of said photovoltaic cell to reduce loss of output power of the plurality of the photovoltaic cells resulting from differences amongst the third optical efficiencies of the plurality of optical concentrators,
the third optical efficiency of each one of the plurality of optical concentrators being dependent on at least a relative positioning of the at least one focusing element, the at least one light guide of said optical concentrator and the corresponding photovoltaic cell for said optical concentrator.

2. The sunlight concentration photovoltaic apparatus of claim 1 wherein the first optical efficiency comprises a measurable difference between an amount of sunlight input at said at least one focusing element and an amount of sunlight output from said at least one focusing element.

3. The sunlight concentration photovoltaic apparatus of claim 1 wherein the at least one focusing element comprises a lens or a curved reflective surface.

4. The sunlight concentration photovoltaic apparatus of claim 2 wherein the first optical efficiency is reduced by an anomaly comprised in the at least one focusing element, the anomaly selected from the group consisting of an optical aberration, material absorption, degradation of at least one sunlight impinging surface, a change in the shape of at least one sunlight impinging surface and any combination thereof.

5. The sunlight concentration photovoltaic apparatus of claim 1 wherein the second optical efficiency comprises a measurable difference between an amount of sunlight input at said least one light guide and an amount of sunlight output from said at least one light guide toward the photovoltaic cell.

6. The sunlight concentration photovoltaic apparatus of claim 5 wherein the second optical efficiency is reduced by an anomaly comprised in the at least one light guide, the anomaly selected from the group consisting of an optical aberration, material absorption, degradation of at least one light impinging surface, a change in the shape of at least one light impinging surface, premature escape of light from the at least one light guide and any combination thereof.

7. The sunlight concentration photovoltaic apparatus of claim 1 wherein each third optical efficiency is dependent on the first optical efficiency of the at least one focusing element.

8. The sunlight concentration photovoltaic apparatus of claim 1 wherein each third optical efficiency is dependent on the first optical efficiency and the second optical efficiency.

9. The sunlight concentration photovoltaic apparatus of claim 1 wherein each third optical efficiency varies over time.

10. The sunlight concentration photovoltaic apparatus of claim 9 wherein each of the integrated power efficiency optimizers continuously adjusts the output voltage and current of the photovoltaic cell with which the integrated power efficiency optimizer is in electrical communication as the third optical efficiency varies over time.

11. The sunlight concentration photovoltaic apparatus of claim 1 wherein each of said sunlight receiver assemblies comprises a substrate bearing said photovoltaic cell and said integrated power efficiency optimizer, and wherein said integrated power efficiency optimizer is disposed proximate to the photovoltaic cell.

12. The sunlight concentration photovoltaic apparatus of claim 1 wherein each of said integrated power efficiency optimizers is powered by at least one corresponding secondary photovoltaic cell.

13. The sunlight concentration photovoltaic apparatus of claim 1 wherein the integrated power efficiency optimizers of said plurality of sunlight receiver assemblies (10) are interconnected in series at a first stage with DC output, the DC output being converted to AC by a DC/AC inverter at a second stage.

14. The sunlight concentration photovoltaic apparatus of claim 1 wherein the integrated power efficiency optimizers of said plurality of sunlight receiver assemblies are interconnected in parallel at a first stage with DC output, the DC output being converted to AC by a DC/AC inverter at a second stage.

15. The sunlight concentration photovoltaic apparatus of claim 1 wherein the integrated power efficiency optimizers of said plurality of sunlight receiver assemblies are interconnected in a combination of series and parallel connections at a first stage with DC output, the DC output being converted to AC by a DC/AC inverter at a second stage.

16. A solar panel comprising the sunlight concentration photovoltaic apparatus of claim 1.

17. A method for conversion of solar power to electrical power by an array of interconnected photovoltaic cells, the method comprising:
for each photovoltaic cell in said array, receiving sunlight through a corresponding optical concentrator adapted to receive input sunlight, the optical concentrator comprising at least one focusing element having a first optical efficiency and at least one light guide having a second optical efficiency, the at least one light guide being optically coupled to the at least one focusing element, each one of the plurality of optical concentrators having a corresponding third optical efficiency, said third optical efficiency being dependent on at least a relative positioning of the at least one focusing element, the at least one light guide of said optical concentrator and the corresponding photovoltaic cell for said optical concentrator;
simultaneously adjusting an output voltage and current of each of the photovoltaic cells in the array to reduce loss of output power of the array resulting from differences amongst the third optical efficiencies of the array and converting an output power of each of the photovoltaic cells in the array using integrated power efficiency optimizers, each one of said integrated power efficiency optimizers being in electrical communication with a corresponding one of the photovoltaic cells; and
combining the converted output power from each of the integrated power efficiency optimizers.

18. The method of claim 17, wherein:
the first optical efficiency comprises a measurable difference between an amount of sunlight input at said at least one focusing element and an amount of sunlight output from said at least one focusing element; and
the second optical efficiency comprises a measurable difference between an amount of sunlight input at said least one light guide and an amount of sunlight output from said at least one light guide.

19. The method of claim 17, wherein each third optical efficiency is dependent on the first optical efficiency and the second optical efficiency.

20. The method of claim 17 wherein adjusting the output voltage and current of each of the photovoltaic cells in the array comprises sensing an output current and an output voltage of each said photovoltaic cell, and locking one of the output current or output voltage to the maximum power point.
